(19) United States
(12) Patent Application Publication
(10) Pub. No.: US 2025/0239440 A1
(43) Pub. Date: Jul. 24, 2025

(54) SUBSTRATE PROCESSING APPARATUS

(71) Applicant: SEMES CO., LTD., Cheonan-si (KR)

(72) Inventors: Yo Han BANG, Cheonan-si (KR); Young Seo AN, Cheonan-si (KR); Dong Young JANG, Cheonan-si (KR); Min Hee HONG, Cheonan-si (KR)

(73) Assignee: SEMES CO., LTD., Cheonan-si (KR)

(21) Appl. No.: 19/031,913

(22) Filed: Jan. 18, 2025

(30) Foreign Application Priority Data
Jan. 19, 2024 (KR) 10-2024-0008991

(51) Int. Cl. H01J 37/32; H01L 21/67

(52) U.S. Cl. CPC H01J 37/32899; H01L 21/67115

(57) ABSTRACT

Disclosed is a substrate processing apparatus. The substrate processing apparatus includes a support unit configured to support a substrate in a lower area of a processing space in a chamber, a heat treatment unit configured to provide energy for heat treatment of the substrate from an upper area of the processing space to the lower area, a plasma generator configured to generate plasma for plasma processing of the substrate in an intermediate area of the processing space, and a space opening/closing unit configured to spatially connect or block the upper area and the intermediate area of the processing space to or from each other. When heat treatment is performed, the space opening/closing unit spatially connects the upper area and the intermediate area to each other, and when plasma processing is performed, the space opening/closing unit spatially blocks the upper area and the intermediate area from each other.

### CROSS-REFERENCE TO THE RELATED APPLICATION

The present application claims priority to and the benefit of Korean Patent Application No. 10-2024-0008991, filed on Jan. 19, 2024, in the Korean Intellectual Property Office, the entire disclosure of which is herein incorporated by reference.

### BACKGROUND

### 1. Field

Embodiments of the present disclosure relate to a substrate processing apparatus used to process a substrate such as a wafer. Particularly, embodiments of the present disclosure relate to a substrate processing apparatus capable of performing a plurality of substrate processing processes in a single substrate processing space.

### 2. Description of the Related Art

In general, various processes for processing a substrate, such as etching and thin film deposition, must be performed in series in order to manufacture semiconductors.

Among substrate processing methods for manufacture of semiconductors, plasma processing using plasma is utilized in various processes. Depending on the type of processing process using plasma, a heat treatment process needs to be performed before or after the plasma processing process in order to improve the characteristics of a substrate and increase the efficiency of the process. This entails a transfer process of transferring the substrate between an apparatus for the plasma processing process and an apparatus for the heat treatment process.

However, it is disadvantageous in terms of improvement of the process speed, and there is limitation in simplifying the structure of equipment and building compact equipment.

### RELATED ART DOCUMENT

### Patent Document

(Patent Document 1) Korean patent Laid-Open Publication No. 10-2009-0005747 (Jan. 14, 2009)

(Patent Document 2) Korean Patent Registration No. 10-1506801 (Mar. 30, 2015)

### SUMMARY

Embodiments of the present disclosure provide a substrate processing apparatus capable of more efficiently performing a substrate processing process.

Embodiments of the present disclosure provide a substrate processing apparatus terms of that is advantageous in simplification and compactness of equipment.

The objects to be accomplished by the disclosure are not limited to the above-mentioned objects, and other objects not mentioned herein will be clearly understood by those skilled in the art from the following description.

According to an embodiment of the present disclosure, a substrate processing apparatus includes a process chamber having a substrate processing space defined therein, the substrate processing space having an upper area, a lower area, and an intermediate area between the upper area and the lower area, a substrate support unit configured to support a substrate in the lower area, a heat treatment unit configured to provide energy for heat treatment of the substrate in a downward direction from the upper area to heat the substrate supported by the substrate support unit, a plasma generator configured to generate plasma for plasma processing of the substrate in the intermediate area, and a space opening/closing unit configured to spatially connect or block the intermediate area to or from the upper area.

The space opening/closing unit may include an opening/closing member configured to be movable between a space-blocking position at which to block the intermediate area from the upper area and a space-opening position deviating from the space-blocking position.

When the heat treatment is performed, the opening/closing member may be located at the space-opening position, and when the plasma processing is performed, the opening/closing member may be located at the space-blocking position.

The plasma generator may include a plasma source configured to form the plasma using process gas. The plasma source may include an upper electrode and a lower electrode. The lower electrode may be disposed in the lower area. The upper electrode may constitute the opening/closing member and may be provided to face the lower electrode when the opening/closing member is located at the space-blocking position.

The space-opening position may be spaced apart from the space-blocking position in a horizontal direction, and the opening/closing member may be movable in the horizontal direction.

The process chamber may include a chamber body having therein the substrate processing space and a housing provided on a wall of the chamber body, the housing having a retreat space defined therein so as to communicate with the substrate processing space and to include the space-opening position. When the heat treatment is performed, the opening/closing member may be moved to the space-opening position and received in the retreat space.

The process chamber may further include a shutter configured to open and close an entrance of the retreat space. The shutter may be configured to be opened and closed by drive force applied thereto.

The housing may protrude outward from the wall of the chamber body.

The opening/closing member may include a plurality of opening/closing blocks divided with respect to the center thereof. The space-opening position may be provided in plural, and the plurality of space-opening positions may be provided in the same number as the plurality of opening/closing blocks.

The plurality of space-opening positions may be provided around the space-blocking position. The plurality of opening/closing blocks may gather at the space-blocking position, and may scatter to the plurality of space-opening positions, respectively.

The opening/closing member may include a sealing member configured to block a gap between the plurality of opening/closing blocks when the plurality of opening/closing blocks gathers. The sealing member may contain a thermally resistive material.

The plasma generator may include a process gas supply unit configured to supply process gas for generation of the plasma. The process gas supply unit may include a showerhead configured to supply the process gas to the intermediate area. The showerhead may constitute the opening/closing member. The showerhead constituting the opening/closing member may be provided to face the substrate support unit when the opening/closing member is located at the space-blocking position.

When the heat treatment is performed, the space opening/closing unit may spatially connect the intermediate area to the upper area, and when the plasma processing is performed, the space opening/closing unit may spatially block the intermediate area from the upper area.

The heat treatment unit may include an infrared lamp, a flash lamp, a laser source, or a microwave source as a thermal source.

The substrate processing apparatus according to the embodiment of the present disclosure may be used to perform an atomic layer deposition (ALD) process, an atomic layer etching (ALE) process, or a chemical vapor deposition (CVD) process as a process of the plasma processing.

According to an embodiment of the present disclosure, a substrate processing apparatus includes a process chamber having a substrate processing space defined therein and a dielectric window provided thereon, the substrate processing space having an upper area, a lower area, and an intermediate area between the upper area and the lower area, a substrate support unit configured to support a substrate in the lower area, a heat treatment unit provided on the dielectric window and configured to provide energy for heat treatment of the substrate in a downward direction from the upper area through the dielectric window to heat the substrate supported by the substrate support unit, and a plasma generator including a process gas supply unit configured to supply process gas to the intermediate area and a plasma source configured to form plasma from the process gas supplied to the intermediate area in order to perform plasma processing on the substrate. The plasma source may include an upper electrode and a lower electrode. The lower electrode may be disposed horizontally in the lower area. The upper electrode may be disposed horizontally and may be provided to be movable between a space-blocking position between the upper area and the intermediate area and a space-opening position spaced apart from the space-blocking position in a horizontal direction to spatially connect or block the intermediate area to or from the upper area in accordance with a movement direction thereof.

When the heat treatment is performed, the upper electrode may be located at the space-opening position to spatially connect the intermediate area to the upper area, and when the plasma processing is performed, the upper electrode may be located at the space-blocking position to spatially block the intermediate area from the upper area.

The upper electrode may include a plurality of unit electrodes divided with respect to the center thereof. The space-opening position may be provided in plural, and the plurality of space-opening positions may be provided in the same number as the plurality of unit electrodes and may be located around the space-blocking position at an interval therefrom. The plurality of unit electrodes may gather at the space-blocking position, and may scatter to the plurality of space-opening positions, respectively.

According to an embodiment of the present disclosure, a substrate processing apparatus includes a process chamber having a substrate processing space defined therein, a substrate support unit configured to support a substrate in a lower area of the substrate processing space, a heat treatment unit configured to provide energy for heat treatment of the substrate from an upper area of the substrate processing space to the substrate supported by the substrate support unit, and a plasma generator including a process gas supply unit configured to supply process gas to an intermediate area between the upper area and the lower area of the substrate processing space and a plasma source configured to form plasma from the process gas supplied to the intermediate area in order to perform plasma processing on the substrate. The plasma source includes an upper electrode and a lower electrode. The lower electrode is disposed horizontally in the lower area. The upper electrode is formed in a plate shape extending in a horizontal direction and is provided to be movable between a space-blocking position between the upper area and the intermediate area and a space-opening position spaced apart from the space-blocking position in the horizontal direction to spatially connect or block the upper area and the intermediate area to or from each other in accordance with a movement direction thereof and to face the lower electrode when located at the space-blocking position. The upper electrode includes a plurality of unit electrodes divided with respect to the center thereof. The space-opening position is provided in plural, and the plurality of space-opening positions is provided in the same number as the plurality of unit electrodes and is located around the space-blocking position at an interval therefrom. The plurality of unit electrodes gathers at the space-blocking position, and scatters to the plurality of space-opening positions, respectively. The process chamber includes a chamber body having therein the substrate processing space and a plurality of housings provided in the same number as the plurality of unit electrodes, the plurality of housings being located on a wall of the chamber body so as to be spaced an interval from each other along a periphery of the wall, each of the plurality of housings having a retreat space defined therein so as to communicate with the substrate processing space and to include the space-opening position. When the heat treatment is performed, each of the plurality of unit electrodes is moved to the space-opening position and is received in the retreat space.

Solutions to solve the above problems may be concretely and clearly understood through embodiments to be described below and the accompanying drawings. In addition, various solutions other than the above solutions may be further provided.

### BRIEF DESCRIPTION OF THE DRAWINGS

The accompanying drawings, which are incorporated in this specification, illustrate exemplary embodiments and serve to further illustrate the technical ideas the disclosure in conjunction with detailed the description of exemplary embodiments that follows, and the disclosure is not to be construed as limited to what is shown in such drawings. In the drawings:

FIGS. 1 and 2 are cross-sectional views showing the configuration of a substrate processing apparatus according to a first embodiment of the present disclosure, wherein FIG. 1 shows a state in which the substrate processing apparatus is in a heat treatment process mode, and FIG. 2 shows a state in which the substrate processing apparatus is in a plasma processing process mode;

FIG. 3 is a perspective cross-sectional view showing an opening/closing member shown in FIGS. 1 and 2;

FIGS. 4 to 6 are cross-sectional views showing operation of the substrate processing apparatus according to the first embodiment of the present disclosure; and

FIG. 7 is a cross-sectional view showing the configuration of a substrate processing apparatus according to a second embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In the following description of the embodiments of the present disclosure, a detailed description of known functions or configurations incorporated herein will be omitted when it may unnecessarily obscure the subject matter of the present disclosure. Throughout the drawings, parts performing similar functions and operations are denoted by the same reference numerals.

At least some of the terms used in this specification are terms defined taking into consideration the functions obtained in accordance with the present disclosure, and may be changed in accordance with the intention of users or operators or usual practice. Therefore, the definitions of these terms should be determined based on the total content of this specification. Additionally, the term “comprise”, “include”, or “have” described herein should be interpreted not to exclude other elements but to further include such other elements unless mentioned otherwise. Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween.

In the drawings, the sizes or shapes of elements and thicknesses of lines may be exaggerated for clarity and convenience of description.

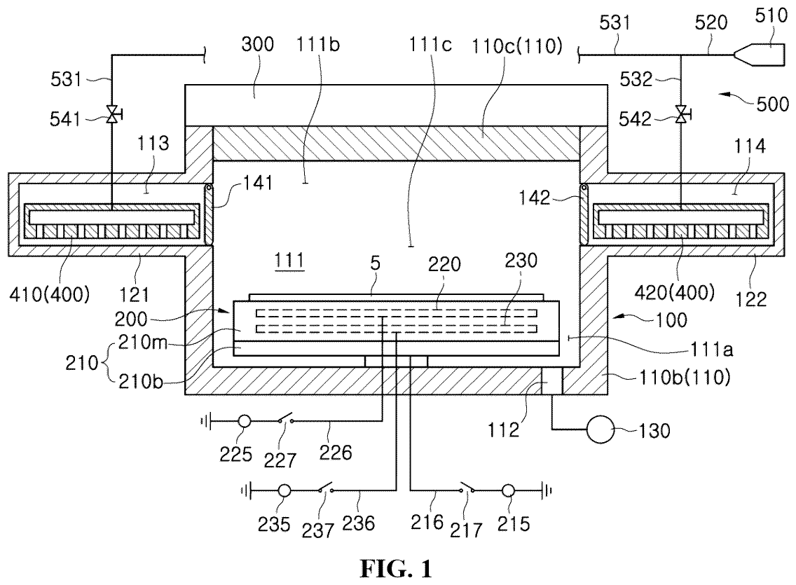

The configuration and operation of a substrate processing apparatus according to an embodiment of the present disclosure are shown in FIGS. 1 to 7. FIGS. 1 to 6 show a substrate processing apparatus according to a first embodiment of the present disclosure.

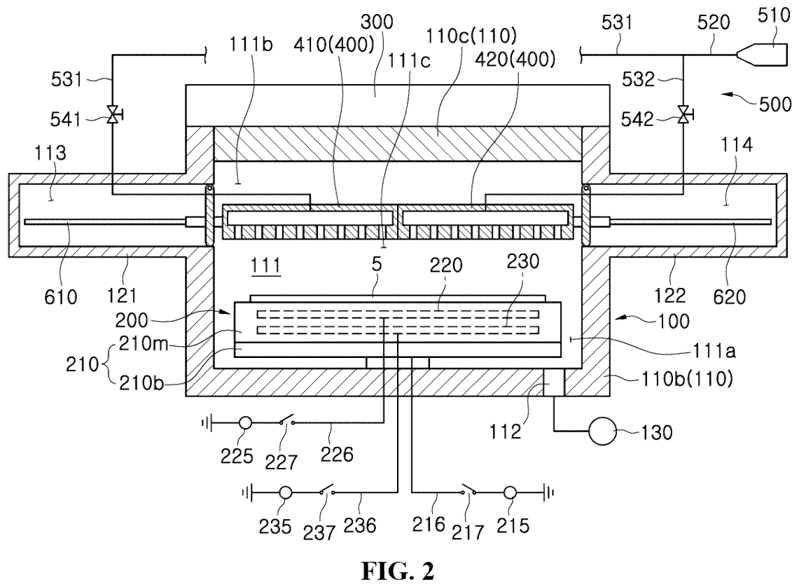

Referring to FIGS. 1 and 2, the substrate processing apparatus according to the first embodiment of the present disclosure includes a process chamber 100 having a single substrate processing space 111 defined therein, and is configured to perform a heat treatment process and a plasma processing process, which are different substrate processing processes, in the substrate processing space 111 in the process chamber 100. For example, the substrate processing apparatus according to the first embodiment of the present disclosure may operate to perform only one of the heat treatment process and the plasma processing process on a substrate 5 and then discharge the substrate 5 out of the substrate processing space 111. Alternatively, the substrate processing apparatus according to the first embodiment of the present disclosure may operate to sequentially perform one (e.g., the heat treatment process) of the heat treatment process and the plasma processing process and the other (e.g., the plasma processing process) thereof and then discharge the substrate 5 out of the substrate processing space 111. Of course, the heat treatment process and the plasma processing process may be repeated in a set order.

The heat treatment process may be performed for modification, annealing, preheating, etc. of the substrate 5. The plasma processing process may be performed for atomic layer deposition (ALD), atomic layer etching (ALE), chemical vapor deposition (CVD), etc.

In order to effectively perform the heat treatment process and the plasma processing process, which are different substrate processing processes, in the single substrate processing space 111, the substrate processing apparatus according to the first embodiment of the present disclosure further includes a substrate support unit 200, a heat treatment unit 300, a plasma generator, and a space opening/closing unit (refer to 400, 610, and 620).

Here, the substrate support unit 200 supports the substrate 5 in a lower area 111a of the substrate processing space 111. The heat treatment unit 300 provides energy for heat treatment of the substrate 5 from an upper area 111b of the substrate processing space 111 to the substrate 5 supported by the substrate support unit 200. The plasma generator is configured to generate plasma for plasma processing of the substrate 5 in an intermediate area 111c between the upper area 111b and the lower area 111a of the substrate processing space 111. The plasma generator includes a process gas supply unit 500 configured to supply process gas to the intermediate area 111c of the substrate processing space 111 and a plasma source configured to form plasma from the process gas supplied to the intermediate area 111c by the process gas supply unit 500. The plasma source includes an upper electrode and a lower electrode. The space opening/closing unit may spatially connect or block the upper area 111b and the intermediate area 111c of the substrate processing space 111 to or from each other.

The process chamber 100 is configured to be able to spatially block the substrate processing space 111 from the outside. The process chamber 100 includes a chamber body 110. The substrate processing space 111 is defined in the chamber body 110. The chamber body 110 includes a lower body 110b formed in a cylindrical shape having an open top and an empty space therein and an upper cover 110c covering the open top of the lower body 110b to seal the lower body 110b.

The lower body 110b may be made of metal such as aluminum (Al) and may be grounded. The upper portion of the chamber body 110 is formed to allow energy from the heat treatment unit 300 for heat treatment of the substrate 5 (hereinafter, reference numeral 5 of the substrate will be omitted) to pass therethrough. To this end, the upper cover 110c of the chamber body 110 may be made of a dielectric material such as quartz. The heat treatment unit 300 is disposed on the upper cover 110c. The energy from the heat treatment unit 300 may pass through the upper cover 110c and then travel downward from the upper area 111b of the substrate processing space 111 in the chamber body 110.

The chamber body 110 is formed to have a substrate loading/unloading port (not shown) communicating with the substrate processing space 111, and the substrate loading/unloading port opened and closed by a port opening/closing unit (not shown). The substrate may be introduced into the substrate processing space 111 through the substrate loading/unloading port to be supported by the substrate support unit 200, and may be discharged outside through the substrate loading/unloading port after completion of processing. The substrate loading/unloading port may be formed in a wall of the lower body 110b.

The chamber body 110 may be formed to have an exhaust port 112 communicating with the substrate processing space 111 defined therein. At least one exhaust port 112 may be formed in the bottom of the chamber body 110. An exhaust unit 130 configured to perform exhaust operation using a vacuum pump may be connected to the exhaust port 112. According to the exhaust operation of the exhaust unit 130, the substrate processing space 111 may be reduced in pressure during the substrate processing process, or by-products generated by plasma processing or the like during the substrate processing process or gases remaining in the substrate processing space 111 may be discharged to the outside.

The substrate support unit 200 includes a substrate chuck 210 configured to chuck the substrate. In addition, the substrate support unit 200 may further include a chuck support supporting the substrate chuck 210 so that the substrate chuck 210 is spaced upward from the bottom of the chamber body 110. The substrate chuck 210 may be an electrostatic chuck (ESC). The electrostatic chuck 210 may include a chuck base 210b and a chuck body 210m stacked on the chuck base 210b in a vertical direction. The chuck body 210m located at a higher position may be formed in a disc shape having a predetermined thickness due to a non-conductive dielectric material. The chuck body 210m may include a chuck electrode 220 and a heater 230, and may be loaded on the chuck base 210b located at a lower position.

The chuck electrode 220 may be provided in the electrostatic chuck 210. That is, the chuck electrode 220 may be embedded in the chuck body 210m. A chuck power supply 225 may be electrically connected to the chuck electrode 220 via a chuck power line 226. The chuck power supply 225 may have a direct-current power supply. A chuck power switch 227 may be provided between the chuck electrode 220 and the chuck power supply 225. For example, the chuck power switch 227 may be provided on the chuck power line 226. Accordingly, the chuck electrode 220 and the chuck power supply 225 may be electrically connected to or disconnected from each other according to on/off operation of the chuck power switch 227. If the chuck power switch 227 is turned on, electrostatic force is generated between the substrate and the chuck electrode 220, so that the substrate may be chucked on the electrostatic chuck 210 by the electrostatic force during the substrate processing process.

The heater 230 may be embedded in the chuck body 210m and may be disposed below the chuck electrode 220. A heater power supply 235 may be electrically connected to the heater 230 via a heater power line 236. The heater 230 may be configured to resist current from the heater power supply 235 to generate high temperatures. In an example, the heater 230 may have a spiral coil. A heater power switch 237 may be provided between the heater 230 and the heater power supply 235. In an example, the heater power switch 237 may be provided on the heater power line 236. The heater 230 and the heater power supply 235 may be electrically connected to or disconnected from each other according to on/off operation of the heater power switch 237. If the heater power switch 237 is turned on during the substrate processing process, heat may be generated from the heater 230. The heat generated from the heater 230 may be transferred to the substrate through the electrostatic chuck 210, and the temperature of the substrate may be raised to or maintained at a temperature required for the substrate processing process by the heat transferred to the substrate.

The chuck base 210b may have a cooling channel (not shown) through which cooling fluid flows. The cooling channel may be provided in the chuck base 210b. The chuck base 210b may include a highly thermally conductive material, and may be cooled by the cooling fluid flowing through the cooling channel. During the substrate processing process, the cooled chuck base 210b may cool the chuck body 210m disposed thereon, and may cool the substrate on the chuck body 210m through the chuck body 210m. Accordingly, the temperature of the substrate may be lowered to or maintained at a temperature required for the substrate processing process.

The substrate support unit 200 may be configured to provide a lower electrode. Accordingly, the lower electrode may be disposed in the lower area 111a of the substrate processing space 111. The lower electrode constitutes at least a portion of the chuck base 210b. The chuck base 210b is a lower electrode member that functions as the lower electrode of the plasma source, and the lower electrode member 210b includes a highly thermally and electrically conductive metal. For example, the material of the lower electrode member 210b may be aluminum. A high-frequency power supply 215 may be electrically connected to the lower electrode member 210b via a high-frequency power line 216, and a high-frequency power switch 217 may be provided between the lower electrode member 210b and the high-frequency power supply 215. The high-frequency power supply 215 may include a radio-frequency (RF) power supply. In an example, the high-frequency power switch 217 may be provided on the high-frequency power line 216. The lower electrode member 210b and the high-frequency power supply 215 may be electrically connected to or disconnected from each other according to on/off operation of the high-frequency power switch 217. If the high-frequency power switch 217 is in the on state, high-frequency power from the high-frequency power supply 215 is supplied to the lower electrode member 210b. The lower electrode member 210b may be formed in a panel shape.

Although not shown, a baffle may be provided along the periphery of the substrate support unit 200 so as to be disposed between the inner wall of the lower body 110b and the periphery of the electrostatic chuck 210. The baffle is formed to have a plurality of process gas passage holes formed therein. The process gas supplied from the process gas supply unit 500 to the intermediate area 111c of the substrate processing space 111 may be discharged through the process gas passage holes in the baffle and the exhaust port 112 according to the exhaust operation of the exhaust unit 130 during the substrate processing process. The flow of the process gas in the substrate processing space 111 may be controlled according to the shapes of the baffle and the process gas passage holes.

The heat treatment unit 300 includes a thermal source. The thermal source may be a rapid thermal source that is more advantageous in rapidly heating the substrate. For example, the heat treatment unit 300 may include one of an infrared (IR) lamp configured to radiate infrared light and a flash lamp configured to generate a flash of light. Alternatively, the heat treatment unit 300 may be provided as a laser radiation unit having a laser source configured to generate a laser or a microwave emission unit having a microwave source configured to generate microwaves. Accordingly, infrared light, a flash of light, a laser, or microwaves may be selected as the energy required to perform heat treatment on the substrate.

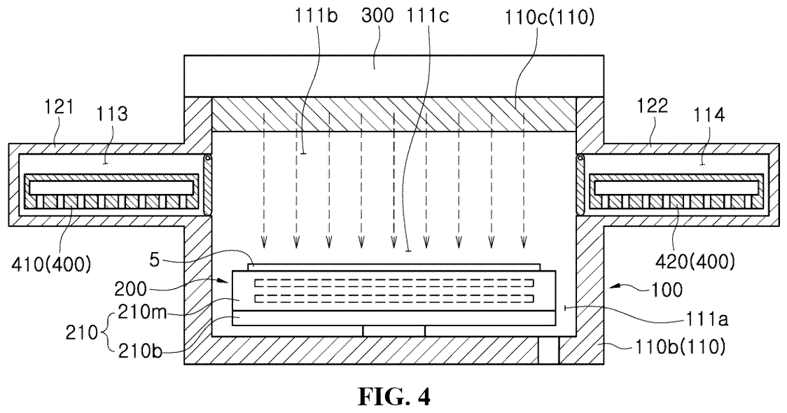

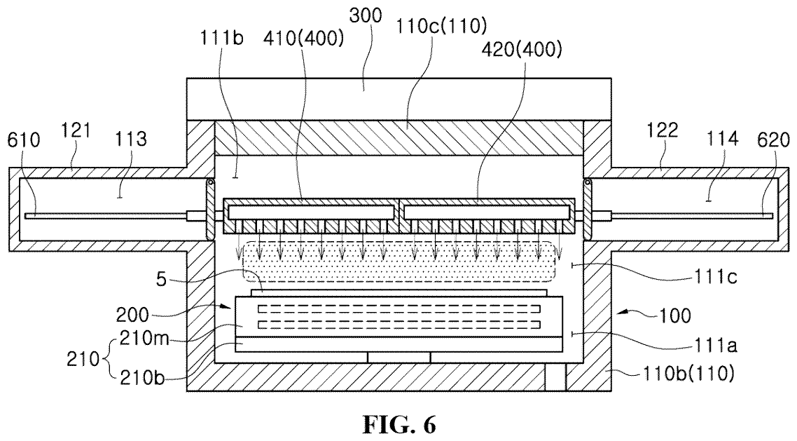

The space opening/closing unit includes an opening/closing member 400. The opening/closing member 400 may be located at a space-blocking position corresponding to an area between the upper area 111b and the intermediate area 111c of the substrate processing space 111, or may be located at a space-opening position (refer to 113 and 114) deviating from the space-blocking position. To this end, the opening/closing member 400 is provided so as to be movable in a reciprocating manner between the space-opening position and the space-blocking position. When the heat treatment process is performed, the opening/closing member 400 may be located at the space-opening position to allow spatial connection between the upper area 111b and the intermediate area 111c of the substrate processing space 111 (refer to FIGS. 1 and 4), and when the plasma processing process is performed, the opening/closing member 400 may be located at the space-blocking position to spatially block the intermediate area 111c of the substrate processing space 111 from the upper area 111b of the substrate processing space 111 (refer to FIGS. 2 and 6).

As shown in FIG. 4, when the opening/closing member 400 is located at the space-opening position, the substrate processing apparatus according to the first embodiment of the present disclosure may smoothly supply energy for heat treatment of the substrate to the substrate supported by the substrate support unit 200 during the heat treatment process. Referring to FIGS. 2 and 6, when the opening/closing member 400 is moved from the space-opening position to the space-blocking position after completion of the heat treatment process, the substrate processing apparatus according to the first embodiment of the present disclosure may suppress, by the opening/closing member 400 located at the space-blocking position, the heat treatment energy remaining in the heat treatment unit 300 or the upper area 111b of the substrate processing space 111 after stop of the operation of the heat treatment unit 300 from being supplied to the substrate.

The process gas supply unit 500 includes a showerhead for evenly supplying and distributing the process gas required to perform the substrate processing process to the intermediate area 111c of the substrate processing space 111. Referring to FIGS. 1 and 2, the opening/closing member 400 may include such as a showerhead. The opening/closing member 400 is provided as a showerhead. Accordingly, the showerhead 400 may supply and distribute the process gas to the intermediate area 111c of the substrate processing space 111, and may be located at the space-opening position (refer to 113 and 114) or the space-blocking position to spatially connect or block the intermediate area 111c and the upper area 111b of the substrate processing space 111 to or from each other.

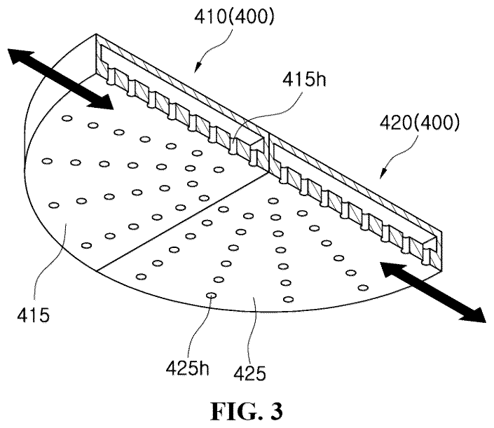

Referring to FIG. 3, the showerhead 400 includes shower plates 415 and 425 having a plurality of process gas discharge holes 415h and 425h formed therein to allow the process gas to be discharged downward therethrough, and is configured to have a structure in which buffer spaces are defined in regions above the shower plates 415 and 425 so as to communicate with the process gas discharge holes 415h and 425h. The showerhead 400 is configured to provide an upper electrode. The upper electrode may constitute at least a portion of the showerhead 400. The shower plates 415 and 425 are upper electrode members that function as the upper electrode of the plasma source, and the upper electrode members 415 and 425 include a highly electrically conductive metal. In an example, the material of the upper electrode members 415 and 425 may be aluminum.

The upper electrode members 415 and 425 (the shower plates) may also be electrically connected to the high-frequency power supply in a manner identical or similar to that of the above-described lower electrode member 210b (the chuck base). Alternatively, the upper electrode members 415 and 425 may be grounded. The plasma source of the plasma generator is a capacitively coupled plasma (CCP) source in which the upper electrode members 415 and 425 functioning as the upper electrode and the lower electrode member 210b functioning as the lower electrode are disposed in the vertical direction in the substrate processing space 111. In order to prevent deterioration in the electromagnetic field distribution uniformity, which is a factor determining the uniformity of the plasma, each of the upper electrode member 415 and 425 and the lower electrode member 210b is provided in a horizontal direction. Further, when the showerhead 400 (the opening/closing member) is located at the space-blocking position, the upper electrode members 415 and 425 and the lower electrode member 210b are disposed so as to directly face each other, as shown in FIGS. 2 and 6.

The space-opening position (refer to the position of the showerhead 400 shown in FIG. 1) is spaced apart from the space-blocking position (refer to the position of the showerhead 400 shown in FIG. 2) in the horizontal direction. Accordingly, the space-opening position and the space-blocking position may be arranged in the horizontal direction. In addition, if the showerhead 400, which is the opening/closing member, is moved from the space-blocking position to the space-opening position, the upper electrode members 415, 425 are located to be misaligned from the lower electrode member 210b, so that the intermediate area 111c and the upper area 111b of the substrate processing space 111 may be spatially connected to each other (refer to FIG. 2). In this state, if the showerhead 400 is moved from the space-opening position to the space-blocking position, the upper electrode members 415 and 425 are located to directly face the lower electrode member 210b, so that the intermediate area 111c of the substrate processing space 111 may be spatially blocked from the upper area 111b of the substrate processing space 111 (refer to FIG. 1). To this end, the space opening/closing unit is configured such that the showerhead 400 (the opening/closing member) is movable in the horizontal direction. In detail, the space opening/closing unit further includes guides 610 and 620 to accurately guide the horizontal movement of the opening/closing member 400, and further includes a drive module to move the opening/closing member 400 in the horizontal direction along the guides 610 and 620.

The showerhead 400 (the opening/closing member) is divided into a plurality of unit showerheads 410 and 420 (opening/closing blocks) with respect to the center of the showerhead. Accordingly, the space-opening position (refer to 113 and 114) is provided in the same number as the plurality of unit showerheads 410 and 420, and the plurality of space-opening positions (refer to 113 and 114) is located around the space-blocking position at a predetermined interval therefrom. The plurality of unit showerheads 410 and 420 may be configured such that the plurality of unit showerheads 410 and 420 are assembled to form the showerhead 400 at the space-blocking position, and are disassembled at the plurality of space-opening positions. The plurality of unit showerheads 410 and 420 may gather together at the space-blocking position to constitute the showerhead 400 (refer to FIGS. 2 and 6), and may move horizontally from the space-blocking position to the plurality of space-opening positions (refer to 113 and 114), respectively, so that the showerhead 400 may be disassembled (refer to FIGS. 1 and 4). According to the configuration in which the showerhead 400 is divided into the plurality of unit showerheads 410 and 420, it is possible to reduce a distance by which the showerhead 400 needs to move horizontally in order to achieve mode switching between the heat treatment process mode and the plasma processing process mode, and accordingly, it is possible to shorten a time required for mode switching. In addition, it is possible to facilitate compactness of the process chamber 100. Each of the upper electrode members 415 and 425 (the shower plates of the unit showerheads) may be connected to the high-frequency power supply or grounded.

The process gas supply unit 500 may supply the process gas to each of the plurality of unit showerheads 410 and 420 at a set flow rate in order to perform plasma processing during the substrate processing process. Referring to FIG. 1, the process gas supply unit 500 may include a process gas source 510, process gas supply lines 520, 531, and 532, and flow control valves 541 and 542. The process gas source 510 may be connected to each of the plurality of unit showerheads 410 and 420 via the process gas supply lines 520, 531, and 532, and may supply a process gas selected from among a plurality of different process gases at a predetermined pressure. The process gas supply lines may include a main line 520 connected to the process gas source 510 and a plurality of branch lines 531 and 532 branching from the main line 520. The branch lines 531 and 532 may be connected to the unit showerheads 410 and 420, respectively. The flow control valves 541 and 542 may be provided on the branch lines 531 and 532, respectively. The flow rates of the process gases that are supplied from the process gas source 510 to the plurality of unit showerheads 410 and 420 via the main line 520 and the plurality of branch lines 531 and 532 may be controlled by the flow control valves 541 and 542, respectively.

Referring to FIGS. 1 and 2, the process chamber 100 further includes a plurality of housings 121 and 122. The plurality of housings 121 and 122 is provided at the chamber body 110 and is provided in the same number as the plurality of unit showerheads 410 and 420 (the opening/closing blocks). The plurality of housings 121 and 122 is disposed on the wall of the lower body 110b so as to be spaced a predetermined interval from each other along the periphery of the lower body 110b. In addition, the plurality of housings 121 and 122 has retreat spaces 113 and 114 defined therein, respectively. The retreat spaces 113 and 114 communicate with the substrate processing space 111 and include the space-opening positions. The unit showerheads 410 and 420 that are moved to the space-opening positions from the space-blocking position in order to achieve mode switching from the plasma processing process mode to the heat treatment process mode may be received in the retreat spaces 113 and 114, respectively. Accordingly, it is possible to minimize damage to the plurality of unit showerheads 410 and 420 due to the heat treatment energy (high temperatures) from the heat treatment unit 300 during the heat treatment process.

The plurality of housings 121 and 122 protrudes outward from the wall of the lower body 110b. According to this configuration, all the retreat spaces 113 and 114 in the housings 121 and 122 are disposed around the chamber body 110. Accordingly, it is possible to allow the plurality of unit showerheads 410 and 420 (the opening/closing blocks) to be located at the space-opening positions without increasing the volume of the substrate processing space 111 to be greater than the volume required for the substrate processing process.

The space opening/closing unit is configured such that the guides 610 and 620 are paired with a plurality of drive modules, respectively, thereby moving the plurality of unit showerheads 410 and 420 (the opening/closing blocks) in the horizontal direction. The plurality of unit showerheads 410 and 420 may be moved together by the space opening/closing unit so as to gather at the space-blocking position or to scatter to the plurality of space-opening positions (refer to 113 and 114). For example, the guides 610 and 620 may be disposed on the left and right of the unit showerheads 410 and 420 in the movement direction of the unit showerheads 410 and 420, thereby guiding horizontal movement of the unit showerheads 410 and 420. In addition, the guides 610 and 620 may extend to be long in the horizontal direction and may be at least partially fixed to the inner walls of the housings 121 and 122 in order to more accurately guide the unit showerheads 410 and 420 to the retreat spaces 113 and 114 including the space-opening positions from the space-blocking position. The guides 610 and 620 may be damaged by high temperatures in the substrate processing space 111 during the substrate processing process. In an embodiment, the guides 610 and 620 are completely disposed in the housings 121 and 121. Alternatively, if each of the guides 610 and 620 is unavoidably formed to have a first portion, which protrudes to the substrate processing space 111 and is thus exposed to high temperatures, and a second portion disposed in a corresponding one of the housings 121 and 122, the first portion may be designed to be as short as possible and made of a highly thermally resistive material. In this way, it is possible to minimize damage to the guides 610 and 620 due to heat.

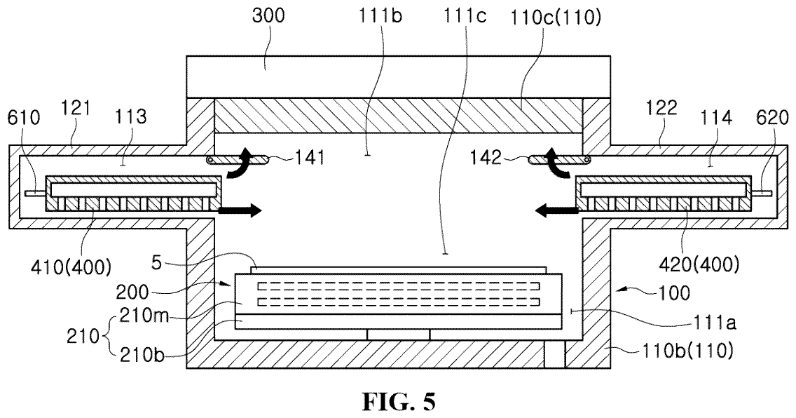

As shown in FIG. 5, the process chamber 100 further includes a plurality of shutters 141 and 142 configured to open and close entrances of the retreat spaces 113 and 114 in the housings 121 and 122, respectively. When the unit showerheads 410 and 420 (the opening/closing blocks) are moved for mode switching between the heat treatment process mode and the plasma processing process mode, the shutters 141 and 142 may maintain the entrances of the retreat spaces 113 and 114 in an open state. During the substrate processing process, the shutters 141 and 142 may maintain the entrances of the retreat spaces 113 and 114 in a closed state, thereby more safely protecting the unit showerheads 410 and 420 (the opening/closing blocks) or the guides 610 and 620 from high temperatures in the substrate processing space 111. The plurality of shutters 141 and 142 may be operated (opened and closed) by drive force applied thereto. In an example, the plurality of shutters 141 and 142 may be provided to be slidable, and may open or close the entrances of the retreat spaces 113 and 114 according to the sliding direction thereof. In another example, the plurality of shutters 141 and 142 may be provided to be rotatable about a horizontal axis, and may open or close the entrances of the retreat spaces 113 and 114 according to the rotational direction thereof.

Although not shown, the showerhead 400 may include a sealing member to block a gap that may occur between the unit showerheads 410 and 420 (the opening/closing blocks) when the unit showerheads 410 and 420 gather at the space-blocking position. Due to the sealing member, when the unit showerheads 410 and 420 gather at the space-blocking position after completion of the heat treatment process, it is possible to prevent heat treatment energy remaining in the heat treatment unit 300 or the upper area 111b of the substrate processing space 111 after stop of the operation of the heat treatment unit 300 from being undesirably supplied to the substrate through a gap between the unit showerheads 410 and 420. For example, the sealing member may be provided on at least one of the surfaces of the unit showerheads 410 and 420 that come into contact with each other when the unit showerheads 410 and 420 gather at the space-blocking position. The sealing member includes a thermally resistive material capable of sufficiently enduring high temperatures. For example, the material of the sealing member may be polytetrafluoroethylene (PTFE), which has excellent heat resistance and durability and a high bending elastic modulus.

As described above, the substrate processing apparatus according to the first embodiment of the present disclosure may perform the heat treatment process or the plasma processing process as the substrate processing process on the substrate in the substrate processing space 111 in the single process chamber 100 through mode switching between the heat treatment process mode and the plasma processing process mode.

When the heat treatment process is performed, the unit showerheads 410 and 420 (the opening/closing blocks) are located at the space-opening positions and thus are received in the retreat spaces 113 and 114 in the housings 121 and 122, respectively. Accordingly, the intermediate area 111c of the substrate processing space 111 is spatially connected to the upper area 111b of the substrate processing space 111, and the heat treatment unit 300 is operated to supply energy for heat treatment of the substrate. When the plasma processing process is performed, the unit showerheads 410 and 420 gather at the space-blocking position to constitute the showerhead 400. Accordingly, the intermediate area 111c of the substrate processing space 111 is spatially blocked from the upper area 111b of the substrate processing space 111. In this state, the process gas supply unit 500 is operated, and the upper electrode members 415 and 425 (the shower plates) and the lower electrode member 210b (the chuck base), which directly face each other, are also operated, thereby generating plasma for plasma processing of the substrate.

In addition, the substrate processing apparatus according to the first embodiment of the present disclosure may rapidly perform modification, annealing, preheating, etc. as the heat treatment process on the substrate through the rapid thermal source. In addition, the substrate processing apparatus according to the first embodiment of the present disclosure operates the heat treatment unit 300 so that the heat treatment unit 300 is preheated during the plasma processing process (when the plasma processing process is performed, because the upper area 111b and the intermediate area 111c of the substrate processing space 111 are spatially blocked from each other by the showerhead 400 (the opening/closing member), it is possible to prevent the heat treatment energy from the heat treatment unit 300 from being supplied to the substrate), thereby shortening a time required to heat the substrate to a required temperature through the heat treatment unit 300 when the heat treatment process is performed after completion of the plasma processing process.

For example, the substrate processing apparatus according to the first embodiment of the present disclosure may sequentially perform the heat treatment process, the ALD process, and the heat treatment thereby performing annealing through heat treatment of the substrate before performing the ALD process and reducing the impurity content in the thin film of the substrate or improving the physical properties of the thin film through heat treatment of the substrate after performing the ALD process. Alternatively, the substrate processing apparatus according to the first embodiment of the present disclosure may sequentially perform the heat treatment process, the ALE process, and the heat treatment process, thereby rapidly raising the temperature of the substrate to a process temperature required for the ALE process through heat treatment of the substrate (i.e., preheating of the substrate) before performing the ALE process and removing the modified surface layer from the substrate through heat treatment of the substrate after performing the ALE process.

In the process of performing the above substrate processing processes, when the mode is switched from the heat treatment process mode to the plasma processing process mode, the showerhead 400 (the opening/closing member) is moved horizontally to the space-blocking position so as to spatially block the intermediate area 111c of the substrate processing space 111 from the upper area 111b of the substrate processing space 111, thereby actively preventing the heat treatment energy remaining in the heat treatment unit 300 or the upper area 111b of the substrate processing space 111 from being supplied to the substrate, and thus increasing a cooling effect with respect to the substrate heated by the heat treatment.

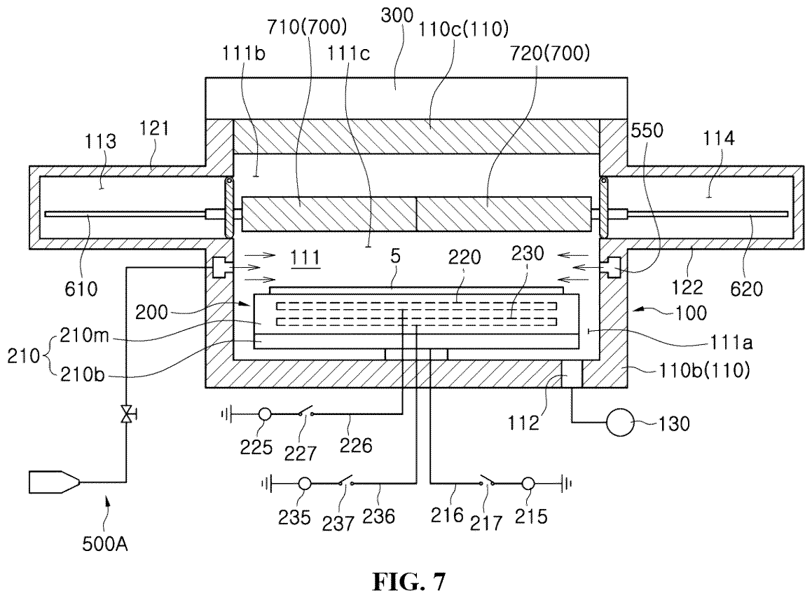

FIG. 7 shows a substrate processing apparatus according to a second embodiment of the present disclosure. In detail, as exemplarily shown in FIG. 7, the opening/closing member may be provided as an upper electrode member 700, rather than the showerhead (reference numeral 400 in FIG. 1).

Referring to FIG. 7, the substrate processing apparatus according to the second embodiment of the present disclosure has the same configuration as the first embodiment, except that the opening/closing member is provided as the upper electrode member 700 functioning as the upper electrode of the plasma source and a process gas supply unit 500A supplies process gas to the intermediate area 111c of the substrate processing space 111 through the wall of the lower body 110b of the chamber body 110.

The upper electrode member 700 may be formed in a flat panel shape. The upper electrode member 700 is divided into a plurality of unit electrode members 710 and 720 with respect to the center of the upper electrode member, similar to the showerhead (reference numeral 400 in FIG. 1) of the first embodiment. Each of the unit electrode members 710 and 720 may be electrically connected to the high-frequency power supply in a manner identical or similar to that of the upper electrode members (the shower plates (reference numerals 415 and 425 in FIG. 1) of the unit showerheads) of the first embodiment, or may be grounded.

The plurality of unit electrode members 710 and 720 may be configured such that the plurality of unit electrode members 710 and 720 are assembled to form the upper electrode member 700 at the space-blocking position, and are disassembled at the plurality of space-opening positions. When the heat treatment process is performed, the unit electrode members 710 and 720 (the opening/closing blocks) are located at the space-opening positions and thus are received in the retreat spaces 113 and 114 in the housings 121 and 122, respectively. Accordingly, the intermediate area 111c of the substrate processing space 111 is spatially connected to the upper area 111b of the substrate processing space 111. When the plasma processing process is performed, the unit electrode members 710 and 720 (the opening/closing blocks) gather at the space-blocking position to constitute the upper electrode member 700. Accordingly, the intermediate area 111c of the substrate processing space 111 is spatially blocked from the upper area 111b of the substrate processing space 111.

The process gas supply unit 500A may evenly supply the process gas to the intermediate area 111c of the substrate processing space 111 through a nozzle module 550 provided in the wall of the lower body 110b.

As is apparent from the above description, according to the embodiment of the present disclosure, a heat treatment process and a plasma processing process, which are different substrate processing processes, may be performed in a single substrate processing space defined in a process chamber. For example, the heat treatment process may be performed before or after performing the plasma processing process. Accordingly, the process speed may increase, and thus units per hour (UPH) may greatly increase. That is, improved process efficiency may be ensured. Further, it is possible to further simplify the structure of equipment and reduce the overall footprint of the equipment.

The effects achievable through the disclosure are not limited to the above-mentioned effects, and other effects not mentioned herein will be clearly understood by those skilled in the art from this specification and the accompanying drawings.

While the present disclosure has been described above, the present disclosure is not limited to the disclosed embodiments and the accompanying drawings, and various modifications and variations can be made by those skilled in the art without departing from the technical spirit of the present disclosure. In addition, the technical features described in the embodiments of the present disclosure may be independently implemented, or two or more technical features may be combined.

What is claimed is:

1. A substrate processing apparatus comprising:
a process chamber having a substrate processing space defined therein;
a substrate support unit configured to support a substrate in a lower area of the substrate processing space;
a heat treatment unit configured to provide energy for heat treatment of the substrate from an upper area of the substrate processing space to the substrate supported by the substrate support unit;
a plasma generator configured to generate plasma for plasma processing of the substrate in an intermediate area between the upper area and the lower area of the substrate processing space; and
a space opening/closing unit configured to spatially connect or block the upper area and the intermediate area of the substrate processing space to or from each other.

2. The substrate processing apparatus as claimed in claim 1,
wherein the space opening/closing unit comprises an opening/closing member configured to be movable between a space-blocking position at which to block the intermediate area from the upper area and a space-opening position deviating from the space-blocking position.

3. The substrate processing apparatus as claimed in claim 2,
wherein, when the heat treatment is performed, the opening/closing member is located at the space-opening position, and
wherein, when the plasma processing is performed, the opening/closing member is located at the space-blocking position.

4. The substrate processing apparatus as claimed in claim 3,
wherein the plasma generator comprises a plasma source configured to form the plasma using process gas,
wherein the plasma source comprises an upper electrode and a lower electrode,
wherein the lower electrode is disposed in the lower area, and
wherein the upper electrode constitutes the opening/closing member and is provided to face the lower electrode when the opening/closing member is located at the

5. The substrate processing apparatus as claimed in claim 3,
wherein the space-opening position is spaced apart from the space-blocking position in a horizontal direction, and
wherein the opening/closing member is movable in the horizontal direction.

6. The substrate processing apparatus as claimed in claim 5,
wherein the process chamber comprises:
a chamber body having therein the substrate processing space; and
a housing provided on a wall of the chamber body, the housing having a retreat space defined therein so as to communicate with the substrate processing space and to include the space-opening position, and
wherein, when the heat treatment is performed, the opening/closing member is moved to the space-opening position and is received in the retreat space.

7. The substrate processing apparatus as claimed in claim 6,
wherein the process chamber further comprises a shutter configured to open and close an entrance of the retreat space.

8. The substrate processing apparatus as claimed in claim 6,
wherein the housing protrudes outward from the wall of the chamber body.

9. The substrate processing apparatus as claimed in claim 3,
wherein the opening/closing member comprises a plurality of opening/closing blocks divided with respect to a center thereof, and
wherein the space-opening position is provided in plural, and the plurality of space-opening positions are provided in the same number as the plurality of opening/closing blocks.

10. The substrate processing apparatus as claimed in claim 9,
wherein the plurality of space-opening positions are provided around the space-blocking position, and
wherein the plurality of opening/closing blocks gather at the space-blocking position, and scatter to the plurality of space-opening positions, respectively.

11. The substrate processing apparatus as claimed in claim 10,
wherein the opening/closing member comprises a sealing member configured to block a gap between the plurality of opening/closing blocks when the plurality of opening/closing blocks gather.

12. The substrate processing apparatus as claimed in claim 11,
wherein the sealing member contains a thermally resistive material.

13. The substrate processing apparatus as claimed in claim 3,
wherein the plasma generator comprises a process gas supply unit configured to supply process gas for generation of the plasma,
wherein the process gas supply unit comprises a showerhead configured to supply the process gas to the intermediate area, and
wherein the opening/closing member constitutes the showerhead and the showerhead is provided to face the substrate support unit when the opening/closing member is located at the space-blocking position.

14. The substrate processing apparatus as claimed in claim 1,
wherein, when the heat treatment is performed, the space opening/closing unit spatially connects the intermediate area to the upper area, and
wherein, when the plasma processing is performed, the space opening/closing unit spatially blocks the intermediate area from the upper area.

15. The substrate processing apparatus as claimed in claim 1,
wherein the heat treatment unit comprises a laser source, a microwave source, an infrared lamp, or a flash lamp.

16. The substrate processing apparatus as claimed in claim 1,
wherein the substrate processing apparatus is used to perform an atomic layer deposition (ALD) process, an atomic layer etching (ALE) process, or a chemical vapor deposition (CVD) process as a process of the plasma processing.

17. A substrate processing apparatus comprising:
a process chamber having a substrate processing space defined therein;
a substrate support unit configured to support a substrate in a lower area of the substrate processing space;
a heat treatment unit configured to provide energy for heat treatment of the substrate from an upper area of the substrate processing space to the substrate supported by the substrate support unit; and
a plasma generator comprising a process gas supply unit configured to supply process gas to an intermediate area between the upper area and the lower area of the substrate processing space and a plasma source configured to form plasma from the process gas supplied to the intermediate area in order to perform plasma processing on the substrate,
wherein the plasma source comprises an upper electrode and a lower electrode,
wherein the lower electrode is disposed horizontally in the lower area, and
wherein the upper electrode is disposed horizontally and is provided to be movable between a space-blocking position between the upper area and the intermediate area and a space-opening position spaced apart from the space-blocking position in a horizontal direction to spatially connect or block the upper area and the intermediate area to or from each other in accordance with a movement direction thereof.

18. The substrate processing apparatus as claimed in claim 17,
wherein, when the heat treatment is performed, the upper electrode is located at the space-opening position to spatially connect the intermediate area to the upper area, and
wherein, when the plasma processing is performed, the upper electrode is located at the space-blocking position to spatially block the intermediate area from the upper area.

19. The substrate processing apparatus as claimed in claim 17,
wherein the upper electrode comprises a plurality of unit electrodes divided with respect to a center thereof,
wherein the space-opening position is provided in plural, and the plurality of space-opening positions are provided in the same number as the plurality of unit electrodes and are located around the space-blocking position at an interval therefrom, and
wherein the plurality of unit electrodes gather at the space-blocking position, and scatters to the plurality of space-opening positions, respectively.

20. A substrate processing apparatus comprising:
a process chamber having a substrate processing space defined therein;
a substrate support unit configured to support a substrate in a lower area of the substrate processing space;
a heat treatment unit configured to provide energy for heat treatment of the substrate from an upper area of the substrate processing space to the substrate supported by the substrate support unit; and
a plasma generator comprising a process gas supply unit configured to supply process gas to an intermediate area between the upper area and the lower area of the substrate processing space and a plasma source configured to form plasma from the process gas supplied to the intermediate area in order to perform plasma processing on the substrate,
wherein the plasma source comprises an upper electrode and a lower electrode,
wherein the lower electrode is disposed horizontally in the lower area,
wherein the upper electrode is formed in a plate shape extending in a horizontal direction and is provided to be movable between a space-blocking position between the upper area and the intermediate area and a space-opening position spaced apart from the space-blocking position in the horizontal direction to spatially connect or block the upper area and the intermediate area to or from each other in accordance with a movement direction thereof and to face the lower electrode when located at the space-blocking position,
wherein the upper electrode comprises a plurality of unit electrodes divided with respect to a center thereof,
wherein the space-opening position is provided in plural, and the plurality of space-opening positions are provided in the same number as the plurality of unit electrodes and are located around the space-blocking position at an interval therefrom,
wherein the plurality of unit electrodes gather at the space-blocking position, and scatters to the plurality of space-opening positions, respectively,
wherein the process chamber comprises:
a chamber body having therein the substrate processing space; and
a plurality of housings provided in the same number as the plurality of unit electrodes, the plurality of housings being located on a wall of the chamber body so as to be spaced apart from each other along a periphery of the wall, each of the plurality of housings having a retreat space defined therein so as to communicate with the substrate processing space and to include the space-opening position, and
wherein, when the heat treatment is performed, each of the plurality of unit electrodes is moved to the space-opening position and is received in the retreat space.
